(19) United States
(12) Patent Application Publication
(10) Pub. No.: US 2007/0164401 A1
(43) Pub. Date: Jul. 19, 2007

(54) Differential transmission line structure and wiring substrate

(75) Inventor: Tsutomu Higuchi, Nagano (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd.

(21) Appl. No.: 11/641,000

(22) Filed: Dec. 19, 2006

(30) Foreign Application Priority Data
Dec. 20, 2005 (JP) P2005-366671

(51) Int. Cl. H01L 39/00

(52) U.S. Cl. 257/662

(57) ABSTRACT

A differential transmission line structure comprises an insulating layer, a grounded conductive layer laminated to the insulating layer, and a differential transmission line formed in the insulating layer. A region in which the conductive layer is removed is formed in correspondence with a position of the differential transmission line.

### TECHNICAL FIELD

The present disclosure relates to a differential transmission line structure and a wiring substrate using the differential transmission line structure.

### RELATED ART

Miniaturization of a differential transmission line structure occupied in electronic components or wiring substrates has been desired from demand for speedup and miniaturization of electronic components or wiring substrates of recent years.

FIGS. 6A and 6B are sectional views schematically showing one example of a related-art differential transmission line structure. Referring first to FIG. 6A, a differential transmission line structure 10 shown in the present view has the so-called microstrip line (MSL) structure. The differential transmission line structure 10 is constructed so that a differential transmission line 17 including wirings 17A, 17B is formed on an insulating layer (dielectric layer) 15 laminated on a conductive layer 14 grounded, and the differential transmission line 17 has a structure covered with a protective layer (insulating layer) 16. Also, the conductive layer 14 is formed on an insulating layer 13 formed on a conductive layer 12, and the conductive layer 12 is formed on a core substrate 11.

Also, a conductive layer 18, an insulating layer 19, a conductive layer 20, an insulating layer 21, a conductive layer 22 and a protective layer (insulating layer) 23 are laminated sequentially from the side of the core substrate 11 on the opposite side of the side, on which the differential transmission line 17 is formed, of the core substrate 11.

Also, referring to FIG. 6B, a differential transmission line structure 30 shown in the present view has the so-called strip line (SL) structure. The differential transmission line structure 30 is constructed so that a differential transmission line 36 including wirings 36A, 36B is formed in an insulating layer (dielectric layer) 33 laminated on a conductive layer 32 grounded, and a conductive layer 34 grounded is formed on the insulating layer 33. Also, a protective layer (insulating layer) 35 is formed on the conductive layer 34.

The insulating layer 33 is formed by laminating an insulating layer (dielectric layer) 33A and an insulating layer (dielectric layer) 33B, and the wirings 36A, 36B are formed on the insulating layer 33A, and the insulating layer 33B is formed so as to cover the wirings 36A, 36B. However, the insulating layers 33A, 33B are actually in harmonious combination and function as one insulating layer 33 substantially.

Also, the conductive layer 32 is formed on a core substrate 31, and via plugs 43, 44 for making connection between the conductive layer 32 and the conductive layer 34 are respectively formed in the insulating layers 33A, 33B.

Also, a conductive layer 37, an insulating layer 38, a conductive layer 39, an insulating layer 40, a conductive layer 41 and a protective layer (insulating layer) 42 are laminated sequentially from the side of the core substrate 31 on the opposite side of the side, on which the differential transmission line 36 is formed, of the core substrate 31.

[Patent Reference 1] Japanese Patent Unexamined Publication No. 2004-14800

[Patent Reference 2] Japanese Patent Unexamined Publication No. 2004-129053

[Patent Reference 3] Japanese Patent Unexamined Publication No. 2005-277028

However, the differential transmission line structure described above had a problem that it becomes difficult to miniaturize a differential transmission line while performing predetermined impedance matching.

For example, in the structure described above, an insulating layer (dielectric layer) is formed by a build-up resin (build-up method), so that a thickness of the insulating layer is generally about 30 to 50 μm. Here, in the case of designing a differential transmission line with, for example, an impedance of 100 ohms, even when a wiring width is decreased to a processing limit (about 20 μm), the need to set a wiring spacing at 1.5 to 2 or more times the wiring width arises.

That is, there are cases where a spacing between wiring and a grounded conductor layer becomes shorter than a spacing between two wirings depending on a thickness of the insulating layer and the wiring width. Further, an electric field extending from the wiring extends in a direction of a conductive layer with a large opposed area, so that an influence of coupling between two opposed wirings reduces and an advantage of the differential transmission line is not taken substantially. Furthermore, a structure body of other wiring etc. cannot be formed in a wiring region extending in a lateral direction and many wiring areas are required.

Also, in order to perform impedance matching in the structure described above, the need to minimize the wiring width arises and a problem of increasing transmission loss arose.

### SUMMARY

Embodiments of the present invention provide a new and useful differential transmission line structure, and a wiring substrate having the differential transmission line structure.

More specifically, embodiments of the present invention provide a differential transmission line structure capable of doing miniaturization while it is easy to perform impedance matching, and a wiring substrate having the differential transmission line structure.

In the first viewpoint of one or more embodiments of the invention, a differential transmission line structure comprises an insulating layer, a grounded conductive layer laminated to the insulating layer, and a differential transmission line formed in the insulating layer, wherein a region in which the conductive layer is removed is formed in correspondence with a position of the differential transmission line.

The differential transmission line structure has features in which miniaturization can be done while it is easy to perform impedance matching.

Also, when a first conductive layer is formed in the upper side of the insulating layer and a second conductive layer is formed in the lower side of the insulating layer and a region in which the first conductive layer and the second conductive layer are removed is formed in correspondence with a position of the differential transmission line, miniaturization can be done while it becomes easy to perform impedance matching of an SL structure.

Also, when a distance from the end of an opening of the conductive layer of a region in which the conductive layer is removed to the differential transmission line is set at a value or more obtained by adding a width of wiring constructing the differential transmission line and a spacing between two wirings constructing the differential transmission line, the impedance matching and miniaturization are more facilitated.

Also, in the second viewpoint of one or more embodiments of the invention, a wiring substrate comprises a differential transmission line structure, the differential transmission line structure having an insulating layer, a grounded conductive layer laminated to the insulating layer, and a differential transmission line formed in the insulating layer, wherein a region in which the conductive layer is removed is formed in correspondence with a position of the differential transmission line.

The wiring substrate has features in which miniaturization can be done while it is easy to perform impedance matching of the transmission line structure.

Also, when a first conductive layer is formed in the upper side of the insulating layer and a second conductive layer is formed in the lower side of the insulating layer and a region in which the first conductive layer and the second conductive layer are removed is formed in correspondence with a position of the differential transmission line, miniaturization can be done while it becomes easy to perform impedance matching of an SL structure.

According to the one or more embodiments, a differential transmission line structure capable of doing miniaturization while it is easy to perform impedance matching, and a wiring substrate having the differential transmission line structure can be provided.

Other features and advantages may be apparent from the following detailed description, the accompanying drawings and the claims.

### BRIEF DESCRIPTION OF THE DRAWINGS

FIG. 1A is a view showing a differential transmission line structure according to a first embodiment (first).

FIG. 1B is a view showing a differential transmission line structure according to the first embodiment (second).

FIG. 2A is a differential transmission line structure for impedance calculation (first).

FIG. 2B is a differential transmission line structure for impedance calculation (second).

FIG. 2C is a differential transmission line structure for impedance calculation (third).

FIG. 3A is a view showing a result of calculation of impedance (first).

FIG. 3B is a view showing a result of calculation of impedance (second).

FIG. 4A is a view showing a differential transmission line structure according to a second embodiment (first).

FIG. 4B is a view showing a differential transmission line structure according to the second embodiment (second).

FIG. 5 is a view showing a wiring substrate according to a third embodiment.

FIG. 6A is a view showing a related-art differential transmission line structure (first).

FIG. 6B is a view showing a related-art differential transmission line structure (second).

### DETAILED DESCRIPTION

A differential transmission line structure according to the invention has an insulating layer, a grounded conductive layer laminated to the insulating layer, and a differential transmission line formed in the insulating layer, and is wherein a region in which the conductive layer is removed is formed in correspondence with a position of the differential transmission line.

In a related-art differential transmission line structure, there were cases where a spacing between wiring and a grounded conductor layer becomes shorter than a spacing between two wirings depending on a thickness of an insulating layer and a wiring width of a differential transmission line. As a result of this, in the case of attempting to miniaturize the transmission line structure, a problem that it becomes difficult to perform impedance matching arose.

On the other hand, in a differential transmission line structure according to the invention, a grounded conductive layer installed in the periphery of a differential transmission line through an insulating layer (dielectric layer) is removed in correspondence with a position of the differential transmission line. As a result of this, it becomes easy to perform impedance matching of the differential transmission line and flexibility of design of a spacing between wirings or a width of wiring of the transmission line improves. As a result of this, the differential transmission line structure can be miniaturized and a wiring substrate using the differential transmission line structure can be miniaturized.

Next, one example of more concrete embodiments of the differential transmission line structure described above will be described below based on the drawings.

### First Embodiment

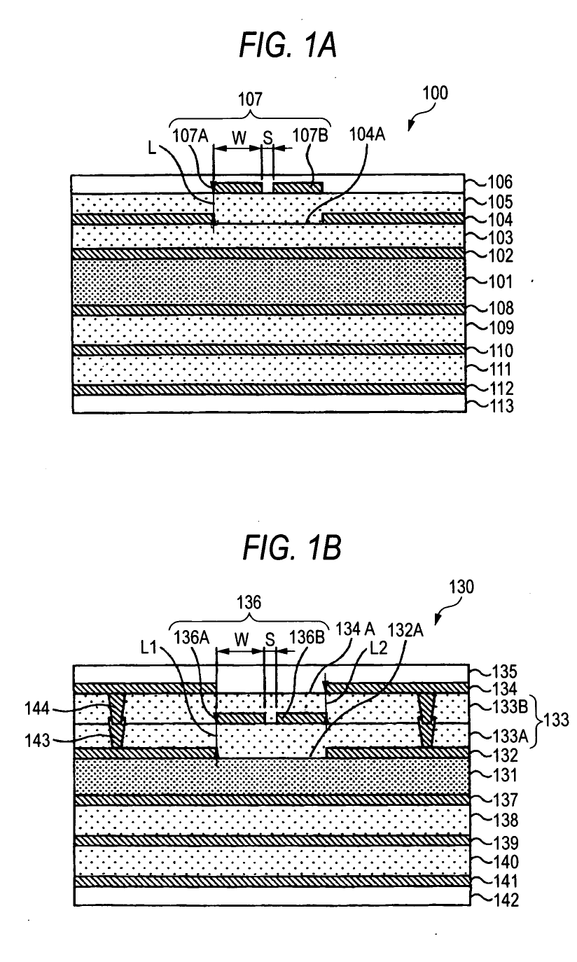

FIGS. 1A and 1B are sectional views schematically showing one example of a differential transmission line structure according to a first embodiment of the invention.

Referring first to FIG. 1A, a differential transmission line structure 100 shown in the present view has the so-called MSL structure. The differential transmission line structure 100 is constructed so that a differential transmission line 107 including wirings 107A, 107B is formed on an insulating layer (dielectric layer) 105 laminated on a conductive layer 104 grounded, and the differential transmission line 107 has a structure covered with a protective layer (insulating layer) 106. Also, the conductive layer 104 is formed on an insulating layer 103 formed on a conductive layer 102, and the conductive layer 102 is formed on a core substrate 101. Also, the conductive layer 102 is grounded.

Also, a conductive layer 108, an insulating layer 109, a conductive layer 110, an insulating layer 111, a conductive layer 112 and a protective layer (insulating layer) 113 are laminated sequentially from the side of the core substrate 101 on the opposite side of the side, on which the differential transmission line 107 is formed, of the core substrate 101.

The differential transmission line structure 100 according to the present embodiment has a feature in which a region (opening 104A) in which the conductive layer 104 is removed is formed in correspondence with the differential transmission line 107. Because of this, a distance from the wirings 107A, 107B constructing the differential transmission line 107 to the grounded conductive layer (for example, the conductive layer 104 or the conductive layer 102) becomes longer than ever before, and an influence of coupling between the grounded conductive layer and the wirings 107A, 107B decreases. As a result of this, an influence of coupling between the wirings 107A, 107B constructing the differential transmission line 107 increases.

As a result of this, it becomes easy to perform impedance matching of the differential transmission line 107. Also, in the case of performing the impedance matching, constraint of a structure of the differential transmission line 107 decreases and an effect capable of decreasing a region occupied by the differential transmission line is obtained. For example, a distance S between the wiring 107A and the wiring 107B can be decreased and the transmission line can be miniaturized. Also, in the case of performing the impedance matching, constraint of wiring width of the wirings 107A, 107B decreases, so that transmission loss can also be suppressed.

Also, an influence of coupling between the grounded conductive layer and the wirings 107A, 107B decreases and an influence of coupling between the wirings 107A, 107B increases relatively, so that effects of becoming resistant to an influence of noise (common mode noise) intruding from the outside of the transmission line and also becoming resistant to an influence of EMI traveling through a ground line are obtained.

Thus, in the differential transmission line structure 100 according to the embodiment, it is easy to perform the impedance matching and also miniaturization can be done and further transmission loss can be suppressed. Also, there is a feature of being resistant to an influence of noise.

Also, when a distance L from the end of the opening 104A to the differential transmission line 107 is set at a value or more obtained by adding a width W of the wiring 107A, 107B and a spacing S between the wirings 107A, 107B, the impedance matching is more facilitated and miniaturization of the differential transmission line is more facilitated.

Also, the structure described above can be applied to, for example, an SL structure as shown in FIG. 1B. Referring to FIG. 1B, a differential transmission line structure 130 shown in the present view has the so-called SL structure. The differential transmission line structure 130 is constructed so that a differential transmission line 136 including wirings 136A, 136B is formed in an insulating layer (dielectric layer) 133 laminated on a conductive layer 132 grounded and a conductive layer 134 grounded is formed on the insulating layer 133. Also, a protective layer (insulating layer) 135 is formed on the conductive layer 134.

The insulating layer 133 is formed by laminating an insulating layer (dielectric layer) 133A and an insulating layer (dielectric layer) 133B, and the wirings 136A, 136B are formed on the insulating layer 133A, and the insulating layer 133B is formed so as to cover the wirings 136A, 136B. However, the insulating layers 133A, 133B are actually in harmonious combination and function as one insulating layer 133 substantially.

Also, the conductive layer 132 is formed on a core substrate 131, and via plugs 143, 144 for making connection between the conductive layer 132 and the conductive layer 134 are respectively formed in the insulating layers 133A, 133B.

Also, a conductive layer 137, an insulating layer 138, a conductive layer 139, an insulating layer 140, a conductive layer 141 and a protective layer (insulating layer) 142 are laminated sequentially from the side of the core substrate 131 on the opposite side of the side, on which the differential transmission line 136 is formed, of the core substrate 131.

In the differential transmission line structure 130 according to the present embodiment, a region (opening 132A) in which the conductive layer 132 formed in the lower side of the insulating layer 133 is removed is formed in correspondence with the differential transmission line 136. The structure 130 has a feature in which a region (opening 134A) in which the conductive layer 134 formed in the upper side of the insulating layer 133 is removed is formed in correspondence with the differential transmission line 136 similarly.

As a result of this, the differential transmission line structure 130 has an effect similar to the differential transmission line structure 100 shown in FIG. 1A. That is, it becomes easy to perform impedance matching of the differential transmission line 136 and also in the case of performing the impedance matching, constraint of a structure of the differential transmission line 136 decreases and an effect capable of decreasing a region occupied by the transmission line is obtained.

For example, a distance S between the wiring 136A and the wiring 136B can be decreased and the transmission line can be miniaturized. Also, in the case of performing the impedance matching, constraint of wiring width of the wirings 136A, 136B decreases, so that transmission loss can also be suppressed.

Also, effects of becoming resistant to an influence of noise (common mode noise) intruding from the outside of the transmission line and also becoming resistant to an influence of EMI traveling through a ground line are obtained.

Also, when a distance L1 from the end of the opening 132A to the differential transmission line 136 is set at a value or more obtained by adding a width W of the wiring 136A, 136B and a spacing S between the wirings 136A, 136B, the impedance matching is more facilitated and miniaturization of the differential transmission line structure is more facilitated.

Similarly, when a distance L2 from the end of the opening 134A to the differential transmission line 136 is set at a value or more obtained by adding the width W of the wiring 136A, 136B and the spacing S between the wirings 136A, 136B, the impedance matching is more facilitated and miniaturization of the differential transmission line structure is more facilitated.

Thus, in the differential transmission line structure 130 according to the embodiment, it is easy to perform the impedance matching and also miniaturization can be done and further transmission loss can be suppressed. Also, there is a feature of being resistant to an influence of noise.

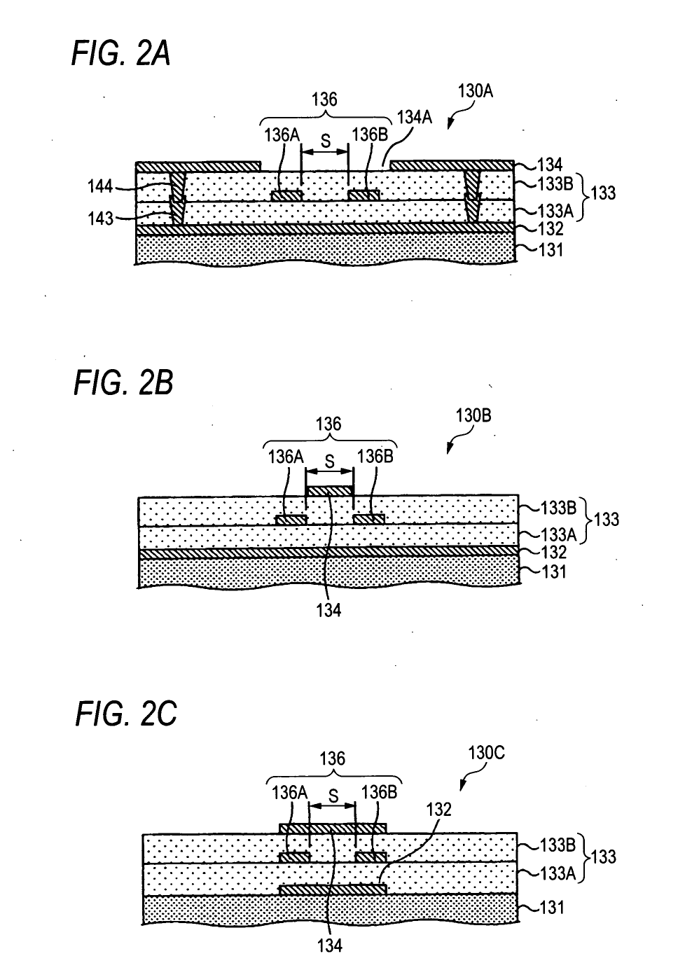

Next, a result of calculating impedance by simulation in the differential transmission line structure 130 according to the embodiment described above will be described below. Also, for comparison, three kinds of differential transmission line structures shown in the following FIGS. 2A to 2C were constructed and impedances were calculated similarly.

FIGS. 2A to 2C are the differential transmission line structures constructed for comparison of impedance measurement. However, in the drawings, the same reference numerals are assigned to the parts described above and the description is omitted. The parts which are not particularly described in the following structures shall be similar to the differential transmission line structure 130 of FIG. 1B.

First, in a differential transmission line structure 130A shown in FIG. 2A, an opening (a region in which a conductive layer is removed) is not formed in a conductive layer 132 and there is a region in which a distance between a differential transmission line 136 and the conductive layer 132 becomes shorter than that of the differential transmission line structure 130.

Also, in a differential transmission line structure 130B shown in FIG. 2B, an opening is not formed in a conductive layer 132 and further a conductive layer 134 is removed in a region distant from a differential transmission line 136.

Also, in a differential transmission line structure 130C shown in FIG. 2C, conductive layers 132, 134 are formed in the portions corresponding to the openings 132A, 134A of the differential transmission line structure 130, and the portion in which the conductive layers are formed and the portion in which the conductive layers are removed are substantially opposite to the differential transmission line structure 130.

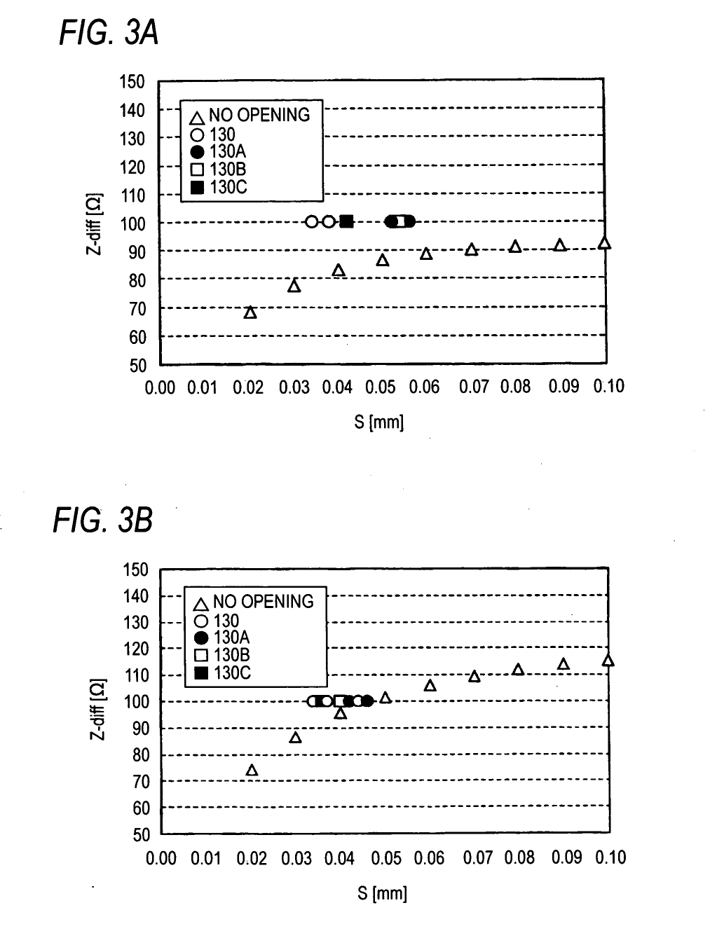

FIGS. 3A and 3B are views showing a result of calculating impedance of the case of changing spacings S between wirings 136A, 136B in the differential transmission lines 130, 130A, 130B, 130C. In addition, a result of the differential transmission line structure (represented as “no opening” in the view) corresponding to the related-art structure in which the openings are not formed in both the conductive layers 132, 134 is together shown for comparison.

In both the cases shown in FIGS. 3A and 3B, thicknesses of the wirings 136A, 136B are set at 15 μm. Also, in the case shown in FIG. 3A, both the thicknesses of insulating layers 133A, 133B are set at 30 μm and in the case shown in FIG. 3B, both the thicknesses of the insulating layers 133A, 133B are set at 50 μm.

Referring first to FIG. 3A, it is found that it is difficult to be matched to 100 ohms which is general impedance of a differential transmission line even when the spacing S is increased in the related-art structure.

On the other hand, in the case of seeing results of the differential transmission line structures 130, 130A, 130B, 130C, impedance can be matched to 100 ohms and it is found that removal of a conductive layer in the vicinity of a differential transmission line facilitates impedance matching. Also, it is found that Scan be minimized when the differential transmission line 130 of the differential transmission line structures 130, 130A, 130B, 130C matches the impedance to 100 ohms. In this case, a region occupied by the differential transmission line can be minimized and the highest degree of flexibility of installation of wiring is obtained.

That is, it is found that it is preferable to remove a conductive layer of a position corresponding to a differential transmission line when a conductive layer grounded is removed.

Also, referring to FIG. 3B, impedance can be matched to 100 ohms when S is increased even in the related-art structure in the case shown in the present view.

However, as in the case shown in FIG. 3A, it is found that it is preferable to remove a conductive layer in order to decrease the spacing S and it is more preferable to remove the conductive layer of a position corresponding to a differential transmission line, that is, to form a structure of the differential transmission line 130.

### Second Embodiment

Also, the differential transmission line structure according to the invention is not limited to the structures shown in the first embodiment. For example, the following structure can also be adopted.

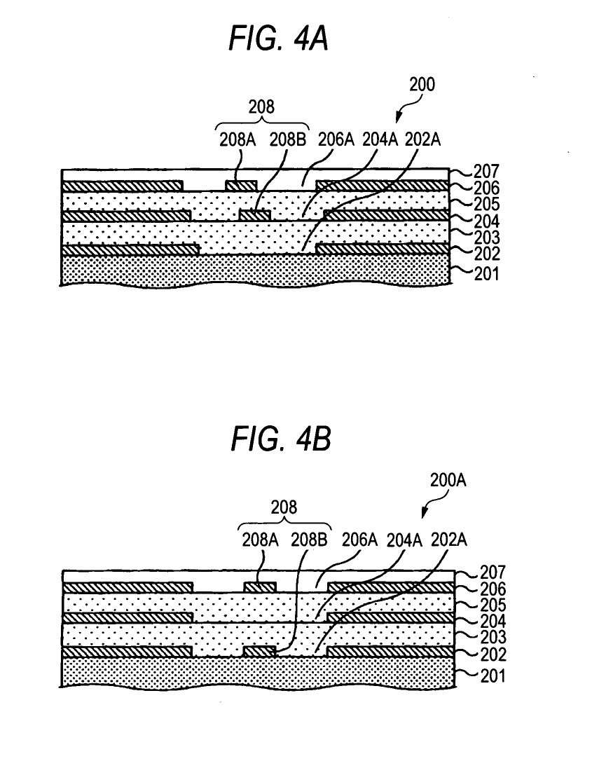

FIGS. 4A and 4B are sectional views schematically showing one example of a differential transmission line structure according to a second embodiment of the invention.

Referring first to FIG. 4A, a differential transmission line structure 200 shown in the present view has a structure in which a conductive layer 202 grounded, an insulating layer (dielectric layer) 203, a conductive layer 204 grounded, an insulating layer (dielectric layer) 205, a conductive layer 206 grounded and a protective layer (insulating layer) 207 are sequentially laminated on a core substrate 201. Also, openings 202A, 204A, 206A are respectively formed in the conductive layers 202, 204, 206.

In the structure described above, wiring 208B is formed in the portion corresponding to the opening 204A on the insulating layer 203 and wiring 208A is formed in the portion corresponding to the opening 206A on the insulating layer 205, respectively, and a differential transmission line 208 is constructed of the wirings 208A, 208B.

Also in the structure described above, regions (the openings 202A, 204A, 206A) in which the conductive layers 202, 204, 206 are removed are formed in correspondence with the differential transmission line 208 and an effect similar to that of the differential transmission line structures 100, 130A described in the first embodiment is obtained.

In the case of the present embodiment, the wiring parts 208A, 208B are respectively formed on different layers of the insulating layers laminated in multiple layers.

Further, the wirings 208A, 208B are formed in a position without overlap in the case of being viewed from the plane, that is, in a state shifted in an oblique direction, so that it becomes easy to ensure a spacing between the wirings 208A, 208B and it becomes easy to match impedance.

Also, FIG. 4B is a view showing a differential transmission line structure 200A which is a modified example of the differential transmission line structure of FIG. 4A. However, in the view, the same reference numerals are assigned to the parts described above and the description is omitted.

In the case shown in the present view, wiring 208B is formed in the portion corresponding to the opening 202A on a core substrate 201 and wiring 208A is formed in the portion corresponding to the opening 206A on an insulating layer 205, respectively, and a differential transmission line 208 is constructed of the wirings 208A, 208B.

In the case of the embodiment, two insulating layers (203, 205) are inserted between the wirings 208A, 208B, so that it becomes easy to ensure a spacing between the wirings 208A, 208B and it becomes easy to match impedance.

### Third Embodiment

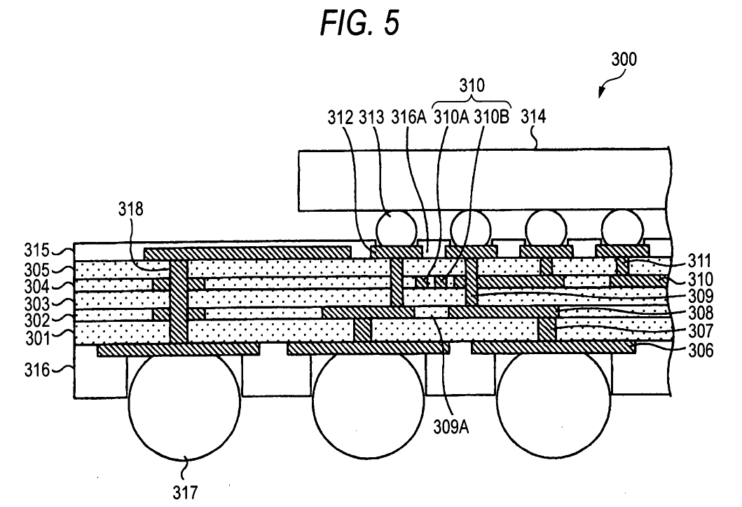

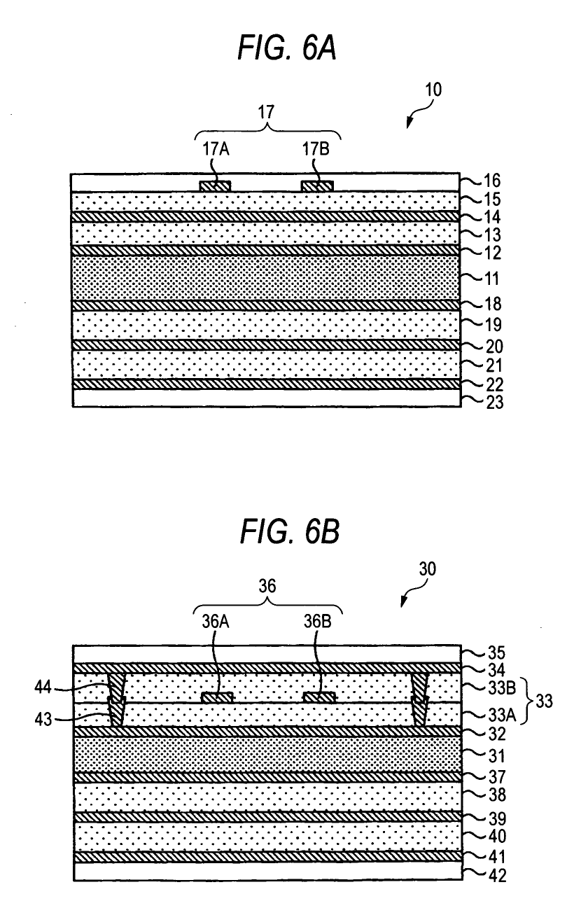

Also, FIG. 5 is a view schematically showing a configuration example of a wiring substrate using the differential transmission line structure.

Referring to FIG. 5, a wiring substrate 300 according to the present embodiment has a structure in which insulating layers 301, 302, 303, 304, 305 made of a build-up resin and formed by, for example, a build-up method are laminated.

Also, pattern wiring 306 is formed on the opposite side of the side, abutting on the insulating layer 302, of the insulating layer 301 and pattern wiring 308 is formed in the insulating layer 302 and pattern wiring 310 is formed in the insulating layer 304 and pattern wiring 312 is formed on the opposite side of the side, abutting on the insulating layer 304, of the insulating layer 305.

Also, via plugs 307 for making connection between the pattern wirings 306, 308, via plugs 309 for making connection between the pattern wirings 308, 310, 312, via plugs 311 for making connection between the pattern wirings 310, 312, and via plugs 318 for making connection between the pattern wirings 306, 308, 310, 312 a reformed in the insulating layers.

Also, a solder resist layer 316 is formed so as to cover the insulating layer 301 and also expose a part of the pattern wiring 306. Solder balls 317 are formed on the pattern wiring 306 exposed from the solder resist layer 316.

Also, a solder resist layer 315 is formed so as to cover the insulating layer 305 and also expose a part of the pattern wiring 312. A semiconductor chip 314 is mounted on the pattern wiring 312 exposed from the solder resist layer 315 through solder balls 313.

In the structure described above, a differential transmission line 310 including wirings 310A, 310B is formed in the insulating layer 304. Also, the pattern wiring 312 which is, for example, a grounded conductive layer (corresponding to the conductive layer 134 of the differential transmission line structure 130) is formed on the insulating layer 305 laminated on the upper side of the differential transmission line 310. In this case, it is found that a region in which a conductive layer corresponding to the opening 134A is removed is ensured as a region 316A.

Also, the pattern wiring 308 which is, for example, a grounded conductive layer (corresponding to the conductive layer 132 of the differential transmission line structure 130) is formed on the insulating layer 302 laminated on the lower side of the differential transmission line 310. In this case, it is found that a region in which a conductive layer corresponding to the opening 132A is removed is ensured as a region 309A.

The structure described above has features in which it becomes easy to perform impedance matching of the differential transmission line 310 and flexibility of design of a spacing between wirings or a width of wiring of the transmission line is large. As a result of this, the differential transmission line structure can be miniaturized and the wiring substrate 300 using the differential transmission line structure can be miniaturized.

Also, in the case of using the differential transmission line structure, effects capable of effectively using space of the wiring substrate and efficiently laying out various pattern wirings, via plugs or devices are obtained.

The invention has been described above with reference to the preferred embodiments, but the invention is not limited to the specific embodiments, and various modifications and changes can be made within the gist described in the claims.

According to the invention, a differential transmission line structure capable of doing miniaturization while it is easy to perform impedance matching, and a wiring substrate having the differential transmission line structure can be provided.

What is claimed is:

1. A differential transmission line structure comprising:
an insulating layer;
a grounded conductive layer laminated to the insulating layer; and
a differential transmission line formed in the insulating layer,
wherein a region in which the conductive layer is removed is formed in correspondence with a position of the differential transmission line.

2. A differential transmission line structure as claimed in claim 1, wherein a first conductive layer is formed in the upper side of the insulating layer and a second conductive layer is formed in the lower side of the insulating layer and a region in which said first conductive layer and said second conductive layer are removed is formed in correspondence with a position of the differential transmission line.

3. A differential transmission line structure as claimed in claim 1, wherein a distance from the end of an opening of said conductive layer of a region in which the conductive layer is removed to the differential transmission line is set at a value or more obtained by adding a width of wiring constructing the differential transmission line and a spacing between two -wirings constructing the differential transmission line.

4. A differential transmission line structure as claimed in claim 1, wherein the differential transmission line is formed in the upper side of the insulating layer and the conductive layer is formed in the lower side of the insulating layer.

5. A wiring substrate comprising:
a differential transmission line structure, the differential transmission line structure having an insulating layer, a grounded conductive layer laminated to the insulating layer, and a differential transmission line formed in the insulating layer,
wherein a region in which the conductive layer is removed is formed in correspondence with a position of the differential transmission line.

6. A wiring substrate as claimed in claim 5, wherein a first conductive layer is formed in the upper side of the insulating layer and a second conductive layer is formed in the lower side of the insulating layer and a region in which said first conductive layer and said second conductive layer are removed is formed in correspondence with a position of the differential transmission line.

7. A wiring substrate as claimed in claim 5, wherein the differential transmission line is formed in the upper side of the insulating layer and the conductive layer is formed in the lower side of the insulating layer.
